(19) United States
(12) Patent Application Publication
(10) Pub. No.: US 2024/0380182 A1
(43) Pub. Date: Nov. 14, 2024

(54) SEMICONDUCTOR LASER DEVICE AND METHOD FOR MANUFACTURING SEMICONDUCTOR LASER DEVICE

(71) Applicant: Mitsubishi Electric Corporation, Tokyo (JP)

(72) Inventor: Atsushi ERA, Tokyo (JP)

(73) Assignee: Mitsubishi Electric Corporation, Tokyo (JP)

(21) Appl. No.: 18/692,234

(22) PCT Filed: Feb. 10, 2022
(86) PCT No.: PCT/JP2022/005357

§ 371 Date: Mar. 14, 2024

(51) Int. Cl. H01S 5/223; H01S 5/22

(52) U.S. Cl. CPC H01S 5/223; H01S 5/2222

(57) ABSTRACT

A semiconductor laser device includes: a ridge having an n-type clad layer, a lower-side light confinement layer, an active layer, and an upper-side light confinement layer which are laminated in this order from a lower side; current blocking layers embedded on both sides of the ridge, the current blocking layers each having a semi-insulating blocking layer covering a side surface of the ridge, an intermediate blocking layer, and an n-type blocking layer which are laminated in this order from the lower side; and a p-type clad layer formed on the ridge and the current blocking layers, in which the ridge has the upper-side light confinement layer as an uppermost layer of the ridge, and the intermediate blocking layer has a higher energy level at a bottom of a conduction band of the intermediate blocking layer compared to the semi-insulating blocking layer.

### FIELD

The present disclosure relates to a semiconductor laser device in which current blocking layers are embedded on both sides of a ridge and a method for manufacturing the semiconductor laser device.

### BACKGROUND

PTL 1 discloses an InP-based semiconductor laser device in which current blocking layers are embedded on both sides of a ridge functioning as an optical waveguide. The ridge of the semiconductor laser device has an n-type clad layer, a lower-side light confinement layer, an active layer, an upper-side light confinement layer, and a p-type clad layer which are laminated in this order from the lower side. The ridge has the p-type clad layer as the uppermost layer of the ridge. The current blocking layer has a semi-insulating blocking layer covering a side surface of the ridge and an n-type blocking layer which are laminated in this order from the lower side.

### CITATION LIST

### Patent Literature

[PTL1]JP 2004-047743 A

### SUMMARY

### Technical Problem

The above-described semiconductor laser device has a problem that large leakage of holes occurs. A leakage path of holes is a path which goes from a p-type clad layer and an upper-side light confinement layer to a semi-insulating blocking layer. A cross-sectional area of this path in a ridge side surface is the summed area of a side surface of the p-type clad layer and a side surface of the upper-side light confinement layer. Thus, the cross-sectional area of the leakage path in the ridge side surface is large, and a leakage current due to holes is also large.

Accordingly, it is assumed that the p-type clad layer is omitted from the ridge and the upper-side light confinement layer becomes the uppermost layer of the ridge. As a result, the leakage path of holes is only a path which goes from the upper-side light confinement layer to the semi-insulating blocking layer. That is, the cross-sectional area of the leakage path in the ridge side surface becomes small. Thus, the leakage current due to holes decreases.

However, only by causing the upper-side light confinement layer to be the uppermost layer of the ridge, a leakage current due to electrons increases. A leakage path of electrons is a path which goes from an n-type clad layer and a lower-side light confinement layer, through the semi-insulating blocking layer, and to an n-type blocking layer. When the upper-side light confinement layer is the uppermost layer of the ridge, the distance from the n-type clad layer to the n-type blocking layer is shorter. As a result, a leakage reduction effect by the semi-insulating blocking layer decreases, and the leakage current due to electrons increases.

The present disclosure has been made to solve the above problems, and an object thereof is to obtain a semiconductor laser device in which a leakage current is reduced.

### Solution to Problem

A semiconductor laser device according to the first invention of the disclosure includes a ridge having an n-type clad layer, a lower-side light confinement layer, an active layer, and an upper-side light confinement layer which are laminated in this order from a lower side; current blocking layers embedded on both sides of the ridge, the current blocking layers each having a semi-insulating blocking layer covering a side surface of the ridge, an intermediate blocking layer, and an n-type blocking layer which are laminated in this order from the lower side; and a p-type clad layer formed on the ridge and the current blocking layers, wherein the ridge has the upper-side light confinement layer as an uppermost layer of the ridge, and the intermediate blocking layer has a higher energy level at a bottom of a conduction band of the intermediate blocking layer compared to the semi-insulating blocking layer.

A semiconductor laser device according to the second invention of the disclosure includes a ridge having an n-type clad layer, a lower-side light confinement layer, and an active layer which are laminated in this order from a lower side; current blocking layers embedded on both sides of the ridge, the current blocking layers each having a semi-insulating blocking layer covering a side surface of the ridge, an intermediate blocking layer, and an n-type blocking layer which are laminated in this order from the lower side; an upper-side light confinement layer formed on the ridge and the current blocking layers; and a p-type clad layer formed on the upper-side light confinement layer, wherein the ridge has the active layer as an uppermost layer of the ridge, and the intermediate blocking layer has a higher energy level at a bottom of a conduction band of the intermediate blocking layer compared to the semi-insulating blocking layer.

A method for manufacturing a semiconductor laser device according to the first invention of the disclosure includes a step of forming a first semiconductor layer on substrate, the first semiconductor layer having an n-type clad layer, a lower-side light confinement layer, an active layer, and an upper-side light confinement layer which are laminated in this order from a lower side; a step of forming a stripe-like mask on the upper-side light confinement layer; a step of etching the first semiconductor layer on both sides of the mask to a halfway position of the n-type clad layer to form a ridge below the mask, the ridge having the upper-side light confinement layer as an uppermost layer of the ridge; a step of embedding current blocking layers on both sides of the ridge, the current blocking layers each having a semi-insulating blocking layer covering a side surface of the ridge, an intermediate blocking layer having a higher energy level at a bottom of a conduction band of the intermediate blocking layer compared to the semi-insulating blocking layer, and an n-type blocking layer which are laminated in this order from the lower side; a step of removing the mask; and a step of forming a second semiconductor layer on the ridge and the current blocking layers, the second semiconductor layer including a p-type clad layer.

A method for manufacturing a semiconductor laser device according to the second invention of the disclosure includes a step of forming a first semiconductor layer on a substrate, the first semiconductor layer having an n-type clad layer, a lower-side light confinement layer, and an active layer which are laminated in this order from a lower side; a step of forming a stripe-like mask on the active layer; a step of etching the first semiconductor layer on both sides of the mask to a halfway position of the n-type clad layer to form a ridge below the mask, the ridge having the active layer as an uppermost layer of the ridge; a step of embedding current blocking layers on both sides of the ridge, the current blocking layers each having a semi-insulating blocking layer covering a side surface of the ridge, an intermediate blocking layer having a higher energy level at a bottom of a conduction band of the intermediate blocking layer compared to the semi-insulating blocking layer, and an n-type blocking layer which are laminated in this order from the lower side; a step of removing the mask; and a step of forming a second semiconductor layer on the ridge and the current blocking layers, the second semiconductor layer having an upper-side light confinement layer and a p-type clad layer which are laminated in this order from the lower side.

### Advantageous Effects of Invention

The uppermost layers of ridges of semiconductor laser devices according to first and second inventions of the present disclosure are an upper-side light confinement layer and an active layer, respectively. In addition, in each of the semiconductor laser devices according to the first and second inventions of the present disclosure, an intermediate blocking layer having a higher energy level at the bottom of the conduction band of the intermediate blocking layer compared to a semi-insulating blocking layer is formed on the semi-insulating blocking layer. Thus, each of the semiconductor laser devices according to the first and second inventions of the present disclosure can reduce a leakage current.

### BRIEF DESCRIPTION OF DRAWINGS

FIG. 1 illustrates a cross section of a semiconductor laser device according to a first embodiment.

FIG. 2 illustrates a cross section of a semiconductor laser device according to the comparative example.

FIG. 3 is a cross-sectional view showing a method for manufacturing the semiconductor laser device according to the first embodiment.

FIG. 4 is a cross-sectional view showing a method for manufacturing the semiconductor laser device according to the first embodiment.

FIG. 5 is a cross-sectional view showing a method for manufacturing the semiconductor laser device according to the first embodiment.

FIG. 6 is a cross-sectional view showing a method for manufacturing the semiconductor laser device according to the first embodiment.

FIG. 7 is a cross-sectional view showing a method for manufacturing the semiconductor laser device according to the first embodiment.

FIG. 8 illustrates a cross section of a semiconductor laser device according to a second embodiment.

FIG. 9 illustrates a cross section of a semiconductor laser device according to a third embodiment.

FIG. 10 is a cross-sectional view showing a method for manufacturing the semiconductor laser device according to a fifth embodiment.

### DESCRIPTION OF EMBODIMENTS

### First Embodiment

FIG. 1 illustrates a cross section of a semiconductor laser device 10 according to a first embodiment.

The semiconductor laser device 10 includes a substrate 12. The substrate 12 is formed of n-type InP.

An n-type clad layer 14 is formed on the substrate 12. The n-type clad layer 14 is formed of n-type InP.

A ridge 22 including the n-type clad layer 14 is formed. The ridge 22 has the n-type clad layer 14, a lower-side light confinement layer 16, an active layer 18, and an upper-side light confinement layer 20 which are laminated in this order from the lower side. The ridge 22 has the upper-side light confinement layer 20 as the uppermost layer of the ridge 22. The lower-side light confinement layer 16 is formed of n-type AlGaInAs. The active layer 18 is formed of undoped AlGaInAs, and a quantum well is formed in the active layer 18. The upper-side light confinement layer 20 is formed of undoped AlGaInAs. The lower-side light confinement layer 16 has a larger band gap than that of the quantum well in the active layer 18 and has a smaller band gap than that of the n-type clad layer 14. The upper-side light confinement layer 20 has a larger band gap than that of the quantum well in the active layer 18 and has a smaller band gap than that of a p-type clad layer 32. The lower-side light confinement layer 16 and the upper-side light confinement layer 20 form a separate confinement heterostructure (SCH).

Current blocking layers 30 are embedded on both sides of the ridge 22. The current blocking layer 30 has a semi-insulating blocking layer 24 covering a side surface of the ridge 22, an intermediate blocking layer 26, and an n-type blocking layer 28 which are laminated in this order from the lower side. The semi-insulating blocking layer 24 is formed of semi-insulating InP doped with Fe. The intermediate blocking layer 26 is formed of p-type InP doped with Zn. The n-type blocking layer 28 is formed of n-type InP.

The p-type clad layer 32 is formed on the ridge 22 and the current blocking layers 30. The p-type clad layer 32 is formed of p-type InP.

A contact layer 34 is formed on the p-type clad layer 32. The contact layer 34 is formed of p-type InGaAs.

Here, as for leakage of holes and electrons, a comparative example and the present embodiment are compared.

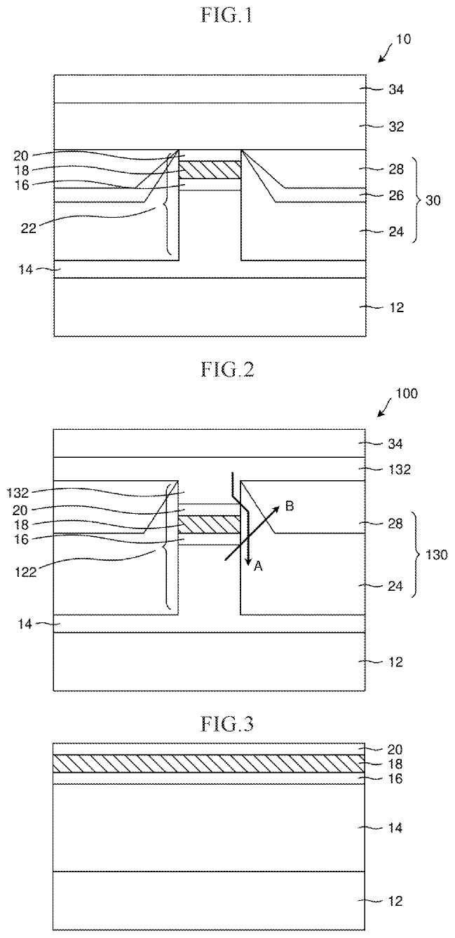

FIG. 2 illustrates a cross section of a semiconductor laser device 100 according to the comparative example. In the semiconductor laser device 100 according to the comparative example, the uppermost layer of a ridge 122 is a p-type clad layer 132. Further, a current blocking layer 130 includes no intermediate blocking layer.

Hole leakage is smaller in the present embodiment than the comparative example. In the comparative example, when holes leak from the ridge 122 to the semi-insulating blocking layer 24, holes pass through both side surfaces of the p-type clad layer 132 and the upper-side light confinement layer 20 in the ridge 122 (arrow A in FIG. 2). In other words, holes pass through the combined surfaces of side surfaces of those two layers. On the other hand, in the present embodiment, holes pass through only the side surfaces of the upper-side light confinement layer 20. That is, in the present embodiment, the cross-sectional area of a leakage path of holes is smaller at a boundary between the ridge 22 and the semi-insulating blocking layer 24. Thus, the hole leakage is smaller in the present embodiment.

When the intermediate blocking layer 26 is not provided, electron leakage is larger in the present embodiment than the comparative example. In the comparative example, when electrons leak from the ridge 122, through the semi-insulating blocking layer 24, to the n-type blocking layer 28, electrons leak from the n-type clad layer 14 and the lower-side light confinement layer 16 to the n-type blocking layer 28 (arrow B in FIG. 2). A leakage path in the present embodiment is similar to the comparative example. However, because the ridge 22 includes no p-type clad layer in the present embodiment, the distance between the n-type clad layer 14 in the ridge 22 and the n-type blocking layer 28 becomes short. Thus, the distance of the semi-insulating blocking layer 24 through which electrons pass when electrons leak becomes short. As a result, the electron leakage becomes larger than that of the comparative example when the intermediate blocking layer 26 is not provided.

However, in the present embodiment, because the intermediate blocking layer 26 is formed, the electron leakage becomes smaller than that of the comparative example. In the present embodiment, the intermediate blocking layer 26 is present between the semi-insulating blocking layer 24 and the n-type blocking layer 28. The p-type intermediate blocking layer 26 serves as an electron barrier having a barrier with a built-in potential against the semi-insulating blocking layer 24 which is semi-insulating. That is, the intermediate blocking layer 26 has a higher energy level at the bottom of the conduction band compared to the semi-insulating blocking layer 24. Thus, the electron leakage is also smaller in the present embodiment.

In FIG. 2, the arrows A and B indicating the leakage paths of holes and electrons are shown only on the right side, but the leakage paths are actually present on the left side also.

A description will hereinafter be made about a method for manufacturing the semiconductor laser device 10 according to the first embodiment.

First, as in FIG. 3, the n-type clad layer 14, the lower-side light confinement layer 16, the active layer 18, and the upper-side light confinement layer 20 are formed on the substrate 12 in this order. In the following, layers from the n-type clad layer 14 to the upper-side light confinement layer 20 will be referred to as first semiconductor layer. As a method for forming the first semiconductor layer, metal organic chemical vapor deposition method (MOCVD method) is used.

Next, as in FIG. 4, a stripe-like mask 36 formed of SiO₂ is formed on the upper-side light confinement layer 20. In a step of forming the mask 36, an SiO₂ layer is first formed on the upper-side light confinement layer 20. Next, the SiO₂ layer is patterned into a stripe-like shape by photo-etching using a resist pattern to form the mask 36.

Next, as in FIG. 5, the first semiconductor layers on both sides of the mask 36 are etched to a halfway position of the n-type clad layer 14 to form the ridge 22 below the mask 36, the ridge 22 having the upper-side light confinement layer as the uppermost layer of the ridge 22. As for the etching, a wafer in the state in FIG. 4 is transported into a chamber of a reactive ion etching (RIE) apparatus, and the etching is thereby carried out while the mask 36 is used as a mask.

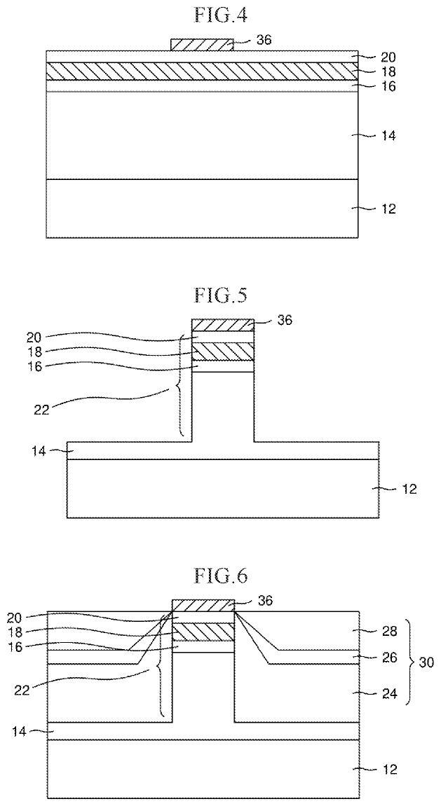

Next, as in FIG. 6, the current blocking layers 30 are embedded on both sides of the ridge 22. In a step of embedding the current blocking layer 30, the semi-insulating blocking layer 24 covering the side surface of the ridge 22, the intermediate blocking layer 26, and the n-type blocking layer 28 are laminated in this order from the lower side by the MOCVD method.

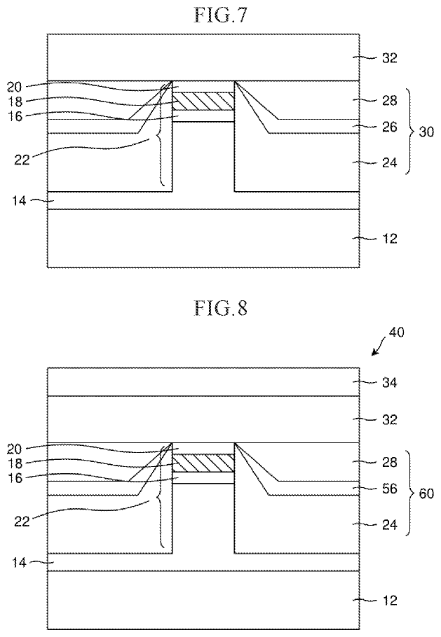

Next, as in FIG. 7, after the mask 36 is removed, the p-type clad layer 32 is formed on the ridge 22 and the current blocking layers 30. In the following, a layer including the p-type clad layer 32 will be referred to as second semiconductor layer. As a method for forming the p-type clad layer 32, the MOCVD method is used.

Next, the contact layer 34 is formed on the p-type clad layer 32. As a method for forming that, the MOCVD method is used. Accordingly, formation of the semiconductor laser device 10 illustrated in FIG. 1 is finished.

Electrodes are thereafter respectively formed above the contact layer 34 and below the substrate 12, but the description will not be made here.

As described above, because the semiconductor laser device 10 according to the present embodiment has the upper-side light confinement layer 20 as the uppermost layer of the ridge 22, the hole leakage is small. Further, because the intermediate blocking layer serving as the electron barrier against the semi-insulating blocking layer is formed on the semi-insulating blocking layer, the electron leakage is small. Thus, in the semiconductor laser device 10, a leakage current is reduced.

Further, because the intermediate blocking layer 26 is formed on the semi-insulating blocking layer 24, lowering of an optical output is inhibited, the lowering being caused due to diffusion of Zn in the intermediate blocking layer 26 into the active layer 18 in an operation of the semiconductor laser device 10. If the intermediate blocking layer is formed between the semi-insulating blocking layer 24 and the ridge 22, Zn in the intermediate blocking layer is diffused into the active layer 18. In the present embodiment, this problem is lessened.

Note that the lower-side light confinement layer 16, the active layer 18, and the upper-side light confinement layer 20 are not limited to AlGaInAs but may be formed of InGaAsP and so forth.

Further, a diffraction grating layer formed of InGaAsP may be formed in an upper portion of the n-type clad layer 14 in the ridge 22.

### Second Embodiment

A semiconductor laser device 40 according to a second embodiment is different from the first embodiment in the point that an intermediate blocking layer 56 is formed of AlInAs. AlInAs can be caused to have a composition having the same lattice constant as InP and, in the composition, has a lower electron affinity compared to InP. Thus, the intermediate blocking layer 56 serves as the electron barrier against the semi-insulating blocking layer 24, and the electron leakage can thereby be inhibited.

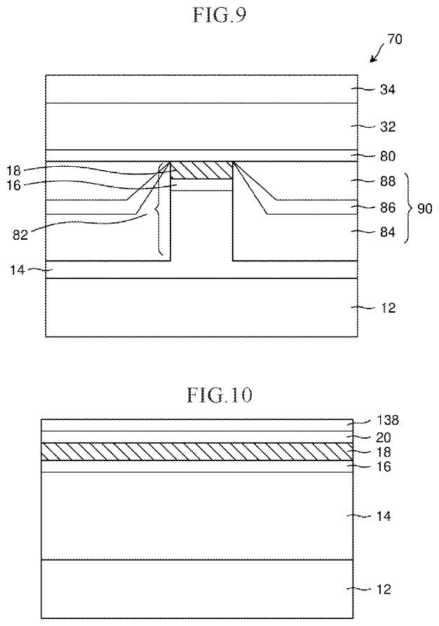

FIG. 8 illustrates a cross section of the semiconductor laser device 40 according to the second embodiment. AlInAs of the intermediate blocking layer 56 may be any of undoped, p-type, and n-type AlInAs. However, when AlInAs is doped with Zn to make AlInAs be p-type, there may be a problem of the diffusion of Zn described in the first embodiment. Further, when AlInAs is made p-type, there may also be a problem of an optical loss due to light absorption in the intermediate blocking layer 56. In order to prevent such problems with the diffusion of Zn and the optical loss, AlInAs is desirably made undoped or n-type AlInAs. Meanwhile, from the viewpoint of inhibition of the election leakage, AlInAs is desirably made p-type in which the electron barrier is enhanced.

Further, because the intermediate blocking layer 56 is formed on the semi-insulating blocking layer 24, lowering of crystal quality of the intermediate blocking layer 56 and lowering of reliability due to stress do not occur. If the intermediate blocking layer is formed from a portion between the semi-insulating blocking layer 24 and the ridge 22 to a portion below the semi-insulating blocking layer 24, AlInAs grows in both of vertical and horizontal directions when the intermediate blocking layer is formed. In this growth, a difference between composition ratios of Al and In occurs in the vertical and horizontal directions, and lattice matching with InP cannot be achieved. As a result, there is a possibility that lowering of the crystal quality of the intermediate blocking layer 56 or lowering of reliability due to stress occurs. In the present embodiment, such problems do not occur.

### Third Embodiment

A semiconductor laser device 70 according to a third embodiment is different from the first embodiment in the point that an upper-side light confinement layer 80 is not included in a ridge 82, the ridge 82 has the active layer 18 at the top of the ridge 82, and an upper-side light confinement layer 80 is formed on the ridge 82 and current blocking layers 90.

FIG. 9 illustrates a cross section of the semiconductor laser device 70 according to the third embodiment. In the present embodiment, because the ridge 82 does not include the upper-side light confinement layer 80, the hole leakage is further inhibited. Thus, the leakage current is further reduced.

In a method for manufacturing the semiconductor laser device 70 according to the third embodiment, the n-type clad layer 14, the lower-side light confinement layer 16, and the active layer 18 are first formed on the substrate 12 in this order. Next, a mask is formed on the active layer 18. the ridge 82 and the current blocking layers 90 are formed, and the mask is removed. Next, the upper-side light confinement layer 80, the p-type clad layer 32, and the contact layer 34 are sequentially formed on the ridge 82 and the current blocking layers 90.

In the present embodiment, the layers from the n-type clad layer 14 to the active layer 18 are the first semiconductor layer, and the layers from the upper-side light confinement layer 80 to the p-type clad layer 32 are the second semiconductor layer.

Note that features of the present embodiment may be combined with features of the second embodiment.

### Fourth Embodiment

A method for manufacturing a semiconductor laser device according to a fourth embodiment is different from the first embodiment in the point that, after a step of removing the mask and before a step of forming the second semiconductor layer, halogen-based etching gas is supplied. Supply of the halogen-based etching gas is performed in the MOCVD apparatus.

By supplying the halogen-based etching gas, an oxide film formed on an upper surface of the upper-side light confinement layer 20 can be removed. AlGaInAs as a material of the upper-side light confinement layer 20 is likely to be oxidized. When a surface of the upper-side light confinement layer 20 is oxidized, an increase in electrical resistance or a loss of light occurs. Furthermore, there is a possibility that the p-type clad layer does not normally grow. In the present embodiment, because the oxide film is removed, those problems do not occur.

As the halogen-based etching gas, t-butyl chloride ((CH₃)₃CCl or TBCl) or hydrogen chloride (HCl) is used. A thickness to be etched is 5 nm, for example. It is desirable that the upper-side light confinement layer 20 is formed to have an extra thickness for the etching. Although the n-type blocking layer 28 is etched to a similar extent in the etching, a slight change in a film thickness of the n-type blocking layer 28 hardly influences the characteristics.

Note that a method for removing the oxide film is not limited to the above etching, and annealing at a high temperature may be carried out, for example. An annealing temperature is 650° C. or higher, for example.

Further, the manufacturing method in the present embodiment may be applied to manufacture of the semiconductor laser device according to the second embodiment or the third embodiment. In a case where the method is applied to manufacture of the semiconductor laser device 70 according to the third embodiment, a portion to be etched is the active layer 18 as the uppermost layer of the ridge 82.

### Fifth Embodiment

A method for manufacturing a semiconductor laser device according to a fifth embodiment is different from the first embodiment in the point that, after a step of forming the first semiconductor layer and before the step of forming the mask, a cap layer 138 formed of InP is formed on the first semiconductor layer (FIG. 10), and after the step of removing the mask and before the step of forming the second semiconductor layer, the cap layer 138 is removed. In the present embodiment, the mask is formed on the cap layer 138.

The cap layer 138 is formed to have a thickness of 3 nm, for example. Removal of the cap layer 138 is carried out by supplying the halogen-based etching gas in the MOCVD apparatus before growth of the second semiconductor layer, similarly to the fourth embodiment. In the etching, for example, a semiconductor layer of 5 nm, which includes the cap layer 138 as the uppermost layer, is etched. By the etching, the cap layer 138 is removed, and the uppermost layer of the ridge below the cap layer 138 is etched by 2 nm. Further, because the cap layer 138 except a portion above the ridge disappears when the ridge is formed, the n-type blocking layer is etched by 5 nm.

In the present embodiment, formation of the oxide film can more certainly be prevented than the fourth embodiment by formation and removal of the cap layer 138.

Further, the manufacturing method in the present embodiment may be applied to manufacture of the semiconductor laser device according to the second embodiment or the third embodiment.

### Reference Signs List

10,40,70 semiconductor laser device, 12 substrate, 14 n-type clad layer, 16 lower-side light confinement layer, 18 active layer, 20,80 upper-side light confinement layer, 22,82 122 ridge, 24,84 semi-insulating blocking layer, 26,56,86 intermediate blocking layer, 28,88 n-type blocking layer, 30,60,90,130 current blocking layer, 32,132 p-type clad layer, 34 contact layer, 36 mask, 138 cap layer

1. A semiconductor laser device comprising:
a ridge having an n-type clad layer, a lower-side light confinement layer, an active layer, and an upper-side light confinement layer which are laminated in this order from a lower side;
current blocking layers embedded on both sides of the ridge, the current blocking layers each having a semi-insulating blocking layer covering a side surface of the ridge, an intermediate blocking layer, and an n-type blocking layer which are laminated in this order from the lower side; and
a p-type clad layer formed on the ridge and the current blocking layers, wherein
the ridge has the upper-side light confinement layer as an uppermost layer of the ridge,
the intermediate blocking layer has a higher energy level at a bottom of a conduction band of the intermediate blocking layer compared to the semi-insulating blocking layer, and
the intermediate blocking layer has a lower electron affinity compared to the semi-insulating blocking layer.

2. A semiconductor laser device comprising:
a ridge having an n-type clad layer, a lower-side light confinement layer, and an active layer which are laminated in this order from a lower side;
current blocking layers embedded on both sides of the ridge, the current blocking layers each having a semi-insulating blocking layer covering a side surface of the ridge, an intermediate blocking layer, and an n-type blocking layer which are laminated in this order from the lower side;
an upper-side light confinement layer formed on the ridge and the current blocking layers; and
a p-type clad layer formed on the upper-side light confinement layer, wherein
the ridge has the active layer as an uppermost layer of the ridge, and
the intermediate blocking layer has a higher energy level at a bottom of a conduction band of the intermediate blocking layer compared to the semi-insulating blocking layer.

3. The semiconductor laser device according to claim 2, wherein
the semi-insulating blocking layer is formed of InP, and
the intermediate blocking layer is formed of p-type InP doped with Zn.

4. The semiconductor laser device according to claim 2, wherein the intermediate blocking layer has a lower electron affinity compared to the semi-insulating blocking layer.

5. The semiconductor laser device according to claim 1, wherein
the semi-insulating blocking layer is formed of InP, and
the intermediate blocking layer is formed of AlInAs.

6. A method for manufacturing a semiconductor laser device, the method comprising:
forming a first semiconductor layer on a substrate, the first semiconductor layer having an n-type clad layer, a lower-side light confinement layer, an active layer, and an upper-side light confinement layer which are laminated in this order from a lower side;
forming a stripe-like mask on the upper-side light confinement layer;
etching the first semiconductor layer on both sides of the mask to a halfway position of the n-type clad layer to form a ridge below the mask, the ridge having the upper-side light confinement layer as an uppermost layer of the ridge;
embedding current blocking layers on both sides of the ridge, the current blocking layers each having a semi-insulating blocking layer covering a side surface of the ridge, an intermediate blocking layer having a higher energy level at a bottom of a conduction band of the intermediate blocking layer compared to the semi-insulating blocking layer and having a lower electron affinity compared to the semi-insulating blocking layer, and an n-type blocking layer which are laminated in this order from the lower side;
removing the mask; and
forming a second semiconductor layer on the ridge and the current blocking layers, the second semiconductor layer including a p-type clad layer.

7. A method for manufacturing a semiconductor laser device, the method comprising:
forming a first semiconductor layer on a substrate, the first semiconductor layer having an n-type clad layer, a lower-side light confinement layer, and an active layer which are laminated in this order from a lower side;
forming a stripe-like mask on the active layer;
etching the first semiconductor layer on both sides of the mask to a halfway position of the n-type clad layer to form a ridge below the mask, the ridge having the active layer as an uppermost layer of the ridge;
embedding current blocking layers on both sides of the ridge, the current blocking layers each having a semi-insulating blocking layer covering a side surface of the ridge, an intermediate blocking layer having a higher energy level at a bottom of a conduction band of the intermediate blocking layer compared to the semi-insulating blocking layer, and an n-type blocking layer which are laminated in this order from the lower side;
removing the mask; and
forming a second semiconductor layer on the ridge and the current blocking layers, the second semiconductor layer having an upper-side light confinement layer and a p-type clad layer which are laminated in this order from the lower side.

8. The method for manufacturing a semiconductor laser device according to claim 6, wherein, after removing the mask and before forming the second semiconductor layer, an oxide film formed on an upper surface of the ridge is removed by supplying halogen-based etching gas.

9. The method for manufacturing a semiconductor laser device according to claim 8, wherein the halogen-based etching gas is t-butyl chloride or hydrogen chloride.

10. The method for manufacturing a semiconductor laser device according to claim 6, wherein, after removing the mask and before forming the second semiconductor layer, an oxide film formed on an upper surface of the ridge is removed by performing annealing at a temperature of 650° C. or higher.

11. The method for manufacturing a semiconductor laser device according to claim 6, wherein,
after forming the first semiconductor layer and before forming the mask, a cap layer covering an upper surface of the first semiconductor layer is formed,
the mask is formed on the cap layer, and
after removing the mask and before forming the second semiconductor layer, the cap layer is removed.

12. The semiconductor laser device according to claim 4, wherein
the semi-insulating blocking layer is formed of InP, and
the intermediate blocking layer is formed of AlInAs.

13. The method for manufacturing a semiconductor laser device according to claim 7, wherein, after removing the mask and before forming the second semiconductor layer, an oxide film formed on an upper surface of the ridge is removed by supplying halogen-based etching gas.

14. The method for manufacturing a semiconductor laser device according to claim 13, wherein the halogen-based etching gas is t-butyl chloride or hydrogen chloride.

15. The method for manufacturing a semiconductor laser device according to claim 7, wherein, after removing the mask and before forming the second semiconductor layer, an oxide film formed on an upper surface of the ridge is removed by performing annealing at a temperature of 650° C. or higher.

16. The method for manufacturing a semiconductor laser device according to claim 7, wherein,
after forming the first semiconductor layer and before forming the mask, a cap layer covering an upper surface of the first semiconductor layer is formed,
the mask is formed on the cap layer, and
after removing the mask and before forming the second semiconductor layer, the cap layer is removed.
